(19) United States
(12) Patent Application Publication
(10) Pub. No.: US 2009/0066229 A1
(43) Pub. Date: Mar. 12, 2009

(54) Top-Emitting Electroluminescent Devices Comprising Cathode Bus Bars

(75) Inventors: Euan C. Smith, Cambridgeshire (GB); William Young, Cambridge (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Cambridge Display Technology Limited, Cambridgeshire (GB)

(21) Appl. No.: 11/915,133

(22) PCT Filed: May 12, 2006
(86) PCT No.: PCT/GB2006/001793

§ 371 Date: Jun. 20, 2008

(30) Foreign Application Priority Data
May 20, 2005 (GB) 0510282.7

(51) Int. Cl. H01J 1/62; H01J 9/20

(52) U.S. Cl. 313/504; 445/24

(57) ABSTRACT

A top-emitting display apparatus is provided having a plurality of pixels, said apparatus comprising an anode formed on a substrate, a well-defining layer, the thickness of said well-defining layer being insufficient for it to serve as a spacer for an evaporation mask, an organic electroluminescent layer formed on the anode in each well of the well-defining layer to form said plurality of pixels, a layer of metal formed on the top surface of the well-defining layer, and a transparent cathode layer deposited such that it is formed both on the electroluminescent layer and the layer of metal on the top surface of the well-defining layer. A method for the manufacture of such an apparatus is also provided.

### FIELD OF THE INVENTION

The present invention relates to top-emitting devices having transparent cathodes with enhanced lateral conductivity and methods for the manufacture thereof.

### BACKGROUND TO THE INVENTION

Displays fabricated using OLEDs (organic light emitting displays) provide a number of advantages over other flat panel technologies. They are bright, colourful, fast-switching, provide a wide viewing angle and are easy and cheap to fabricate on a variety of substrates. Organic (which here includes organometallic) LEDs may be fabricated using materials including polymers, small molecules and dendrimers, in a range of colours which depend upon the materials employed. Examples of polymer-based organic LEDs are described in WO 90/13148, WO 95/06400 and WO 99/48160; examples of dendrimer-based materials are described in WO 99/21935 and WO 02/067343; and examples of so called small molecule based devices are described in U.S. Pat. No. 4,539,507.

A typical OLED device comprises two layers of organic material, one of which is a layer of light emitting material such as a light emitting polymer (LEP), oligomer or a light emitting low molecular weight material, and the other of which is a layer of a hole transporting material such as a polythiophene derivative or a polyaniline derivative.

OLEDs may be deposited on a substrate in a matrix of pixels to form a single or multi-colour pixellated display. A multicoloured display may be constructed using groups of red, green, and blue emitting pixels. So-called active matrix displays have a memory element, typically a storage capacitor and a transistor, associated with each pixel whilst passive matrix displays have no such memory element and instead are repetitively scanned to give the impression of a steady image. Other passive displays include segmented displays in which a plurality of segments share a common electrode and a segment may be lit up by applying a voltage to its other electrode. A simple segmented display need not be scanned but in a display comprising a plurality of segmented regions the electrodes may be multiplexed (to reduce their number) and then scanned.

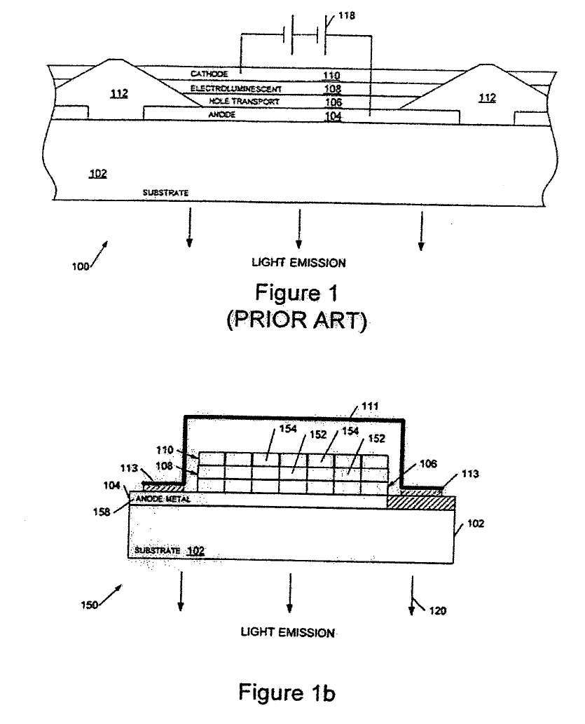

FIG. 1 shows a vertical cross section through an example of an OLED device 100. In an active matrix display part of the area of a pixel is occupied by associated drive circuitry (not shown in FIG. 1). The structure of the device is somewhat simplified for the purposes of illustration.

The OLED 100 comprises a substrate 102, typically 0.7 mm or 1.1 mm glass but optionally clear plastic or some other substantially transparent material. An anode layer 104 is deposited on the substrate, typically comprising around 150 nm thickness of ITO (indium tin oxide), over part of which is provided a metal contact layer. Typically the contact layer comprises around 500 nm of aluminium, or a layer of aluminium sandwiched between layers of chrome, and this is sometimes referred to as anode metal. Glass substrates coated with ITO and contact metal are available from Corning, USA. The contact metal over the ITO helps provide reduced resistance pathways where the anode connections do not need to be transparent, in particular for external contacts to the device. The contact metal is removed from the ITO where it is not wanted, in particular where it would otherwise obscure the display, by a standard process of photolithography followed by etching.

A substantially transparent hole transport layer 106 is deposited over the anode layer, followed by an electroluminescent layer 108, and a cathode 110. The electroluminescent layer 108 may comprise, for example, a PPV (poly(p-phenylenevinylene)) and the hole transport layer 106, which helps match the hole energy levels of the anode layer 104 and electroluminescent layer 108, may comprise a conductive transparent polymer, for example PEDOT:PSS (polystyrene-sulphonate-doped polyethylene-dioxythiophene) from Bayer AG of Germany. In a typical polymer-based device the hole transport layer 106 may comprise around 200 nm of PEDOT; a light emitting polymer layer 108 is typically around 70 nm in thickness.

These organic layers may be deposited by spin coating (afterwards removing material from unwanted areas by plasma etching or laser ablation) or by inkjet printing. In this latter case banks 112 may be formed on the substrate, for example using photoresist, to define wells into which the organic layers may be deposited. Such wells define light emitting areas or pixels of the display.

Cathode layer 110 typically comprises a low work function metal such as calcium or barium (for example deposited by physical vapour deposition) covered with a thicker, capping layer of aluminium. Optionally an additional layer may be provided immediately adjacent the electroluminescent layer, such as a layer of lithium fluoride, for improved electron energy level matching. Mutual electrical isolation of cathode lines may achieved or enhanced through the use of cathode separators (not shown in FIG. 1).

The same basic structure may also be employed for small molecule devices.

Typically a number of displays are fabricated on a single substrate and at the end of the fabrication process the substrate is scribed, and the displays separated before an encapsulating can is attached to each to inhibit oxidation and moisture ingress.

To illuminate the OLED power is applied between the anode and cathode, represented in FIG. 1 by battery 118. In the example shown in FIG. 1 light is emitted through transparent anode 104 and substrate 102 and the cathode is generally reflective; such devices are referred to as “bottom emitters”. Devices which emit through the cathode (“top emitters”) may also be constructed, for example by keeping the thickness of cathode layer 110 less than around 50-100 nm so that the cathode is substantially transparent.

Organic LEDs may be deposited on a substrate in a matrix of pixels to form a single or multi-colour pixellated display. A multicoloured display may be constructed using groups of red, green, and blue emitting pixels. In such displays the individual elements are generally addressed by activating row (or column) lines to select the pixels, and rows (or columns) of pixels are written to, to create a display. So-called active matrix displays have a memory element, typically a storage capacitor and a transistor, associated with each pixel whilst passive matrix displays have no such memory element and instead are repetitively scanned, somewhat similarly to a TV picture, to give the impression of a steady image.

Referring now to FIG. 1b, this shows a simplified cross-section through a passive matrix OLED display device 150, in which like elements to those of FIG. 1 are indicated by like reference numerals. As shown the hole transport 106 and electroluminescent 108 layers are subdivided into a plurality of pixels 152 at the intersection of mutually perpendicular anode and cathode lines defined in the anode metal 104 and cathode layer 110 respectively. In the figure conductive lines 154 defined in the cathode layer 110 run into the page and a cross-section through one of a plurality of anode lines 158 running at right angles to the cathode lines is shown. An electroluminescent pixel 152 at the intersection of a cathode and anode line may be addressed by applying a voltage between the relevant lines. The anode metal layer 104 provides external contacts to the display 150 and may be used for both anode and cathode connections to the OLEDs (by running the cathode layer pattern over anode metal lead-outs).

The above mentioned OLED materials, and in particular the light emitting polymer material and the cathode, are susceptible to oxidation and to moisture. The device is therefore encapsulated in a metal can 111, attached by UV-curable epoxy glue 113 onto anode metal layer 104, small glass beads within the glue preventing the metal can touching and shorting out the contacts. Preferably the anode metal contacts are thinned where they pass under the lip of the metal can 111 to facilitate exposure of glue 113 to UV light for curing.

Considerable effort has been dedicated to the realization of a full-colour, all plastic screen. The major challenges to achieving this goal have been: (1) access to conjugated polymers emitting light of the three basic colours red, green and blue; and (2) the conjugated polymers must be easy to process and fabricate into full-colour display structures. PLED devices show great promise in meeting the first requirement, since manipulation of the emission colour can be achieved by changing the chemical structure of the conjugated polymers. However, while modulation of the chemical nature of conjugated polymers is often easy and inexpensive on the lab scale it can be an expensive and complicated process on the industrial scale. The second requirement of the easy processability and build-up of full-colour matrix devices raises the question of how to micro-pattern fine multicolour pixels and how to achieve full-colour emission. Inkjet printing and hybrid inkjet printing technology have attracted much interest for the patterning of PLED devices (see, for example, R. F. Service, Science 1998, 279, 1135; Wudl et al., Appl. Phys. Lett. 1998, 73, 2561; J. Bharathan, Y. Yang, Appl. Phys. Lett. 1998, 72, 2660; and T. R. Hebner, C. C. Wu, D. Marcy, M. L. Lu, J. Sturm, Appl. Phys. Lett. 1998, 72, 519).

In order to contribute to the development of a full-colour display, conjugated polymers exhibiting direct colour-tuning, good processability and the potential for inexpensive large-scale fabrication have been sought. The step-ladder polymer poly-2,7-fluorenes have been the subject of much research into blue-light emitting polymers (see, for example, A. W. Grice, D. D. C. Bradley, M. T. Bernius, M. Inbasekaran, W. W. Wu, and E. P. Woo, Appl. Phys. Lett. 1998, 73, 629; J. S. Kim, R. H. Friend, and F. Cacialli, Appl. Phys. Lett. 1999, 74, 3084; WO-A-00/55927 and M. Bernius et al., Adv. Mater., 2000, 12, No. 23, 1737).

As noted above, active matrix organic light-emitting devices (AMOLEDs) are known in the art wherein electroluminescent pixels and a cathode are deposited onto a glass substrate comprising active matrix circuitry for controlling individual pixels and a transparent anode. Light in these devices is emitted towards the viewer through the anode and the glass substrate (so-called bottom-emission), however a substantial proportion of the light generated within the electroluminescent layer is absorbed by the active matrix circuitry. Devices with transparent cathodes (so-called “top-emitting” devices) have been developed as a solution to this problem. A transparent cathode must possess the following properties:

transparency

conductivity

low workfunction for efficient electron injection into the LUMO of the electroluminescent layer of the device or, if present, the electron transporting layer.

However, there are very few conductive materials that are transparent at anything above very low thicknesses. One such material is indium tin oxide (ITO), and thus examples of transparent cathodes disclosed in the art include MgAg/ITO disclosed in Appl. Phys. Lett 68, 2606, 1996 and Ca/ITO disclosed in J. Appl. Phys. 87, 3080, 2000.

In these examples a first, thin layer of metal (or metal alloy in the case of MgAg) provides electron injection. However, the thinness of this layer is such that lateral conductivity is poor. A layer of ITO is necessary because it retains transparency at higher thicknesses, thus improving lateral conductivity of the cathode.

However, ITO is deposited by the high energy process of sputtering which is likely to cause damage to the layer(s) it is deposited onto. Given this, and the constraints in terms of alternatives to ITO, it would therefore be desirable if the need for a separate layer of transparent conductive material can be obviated.

Bus-bars are a well known method of increasing the conductivity of a conductive layer (see, for example, U.S. Pat. No. 6,664,730), providing a thickening of the metal away from the active region. However, unless these bus-bars are transparent, it will be immediately apparent that their use in top-emitting devices will reduce the emissive area of pixels in the same way that active matrix circuitry does for bottom-emitting AMOLEDs, thus reducing the advantages associated with said devices.

### SUMMARY OF THE INVENTION

Inkjet printing of electroluminescent formulations is a cheap and effective method of forming patterned devices. As disclosed in EP-A-0880303, this entails use of photolithography to form wells that define pixels into which the electroluminescent material is deposited by inkjet printing. The present inventors have solved the problem of trying to enhance the conductivity of these thin transparent cathode layers in top-emitting devices without reducing emissive area of pixels by utilising the well-defining resist banks to provide structures on which a patterned metal layer can be deposited to give bus-bars. Deposition of a metal layer over the well-forming photoresist layer provides increased lateral conductivity for a transparent cathode. The emissive area is not reduced by use of this metal layer because it is only located over photoresist material. Moreover, the metal layer can function as a mask for patterning the photoresist used to form wells for inkjet printing and it also provides better continuity over the well-forming banks.

Thus, in a first aspect of the present invention there is provided a top-emitting display apparatus having a plurality of pixels, said apparatus comprising:

an anode formed on a substrate;

a well-defining layer, the thickness of said well-defining layer being insufficient for it to serve as a spacer for an evaporation mask;

an organic electroluminescent layer formed on the anode in each well of the well-defining layer to form said plurality of pixels;

a layer of metal formed on the top surface of the well-defining layer; and

a transparent cathode layer deposited such that it is formed both on the electroluminescent layer and the layer of metal on the top surface of the well-defining layer.

The layer of metal on the top surface of the well-defining layer provides bus-bars that are able to enhance the conductivity of the transparent cathode layer which it is in contact with. Because the bus-bars provided by this metal layer are deposited on areas of the device that are already non-emissive due to the presence of the well-defining banks, the conductivity of the transparent cathode layer is enhanced without reducing the emissive area of the pixels.

The metal on the top surface may be any metal having a suitable conductivity, and suitable examples will be readily apparent to those skilled in the field. Preferred examples include aluminium and chromium. The metal may be deposited on the top surfaces of the well-defining photoresist layer by any means apparent to those skilled in the field. For example, the metal may be deposited by thermal evaporation. Typically, the thickness of this layer is 0.1-1 μm.

The well-defining layer may be formed from a photoresist patterned using a suitable photomask. Alternatively, the well-defining layer may be an etchable material, in particular an etchable polyimide, that may be patterned to form the well-defining layer by a wet etch or a dry etch process. Preferably, the well-defining layer is a photoresist.

In a preferred embodiment, the layer of metal and the well-defining layer are self-aligned. In other words, the metal layer is patterned from (one of) the same mask(s) as that used to pattern the well-defining layer. This has the advantage that it simplifies the manufacturing process and that there are no additional alignment tolerances such that it ensures minimisation of the reduction of the emissive area.

The transparent cathode may comprise any low work-function conductive material that will allow the passage of at least some light through it. For example, the transparent cathode may have a light transmissivity of at least 20%, preferably a light transmissivity of at least 30%, more preferably a light transmissivity of at least 50%, and most preferably a light transmissivity of at least 60%. The transparent cathode may comprise a single layer of conductive material or a plurality of layers. Particularly preferred transparent cathode arrangements are:

(a) a low work-function metal sufficiently thin to be transparent in contact with the electroluminescent layer. Preferred low work-function materials have a work-function of no more than 3.5 eV, preferably no more than 3.2 eV, most preferably no more than 3.0 eV. Alkaline earth metals having these work-functions in this range, in particular barium or calcium, are particularly preferred. Thin low work-function materials may be deposited by relatively low energy processes such as thermal or electron beam evaporation that do not cause any damage to electroluminescent layer.

(b) a thin layer of dielectric material capped with a thin metal layer. Preferred dielectric materials are metal oxides or fluorides, preferably fluorides. Preferred metal cations are alkaline or alkaline earth metals. Particularly preferred are fluorides of lithium, sodium, calcium and barium. Any thin metal layer may serve to cap the dielectric layer provided it retains its transparency, for example aluminium.

Typically, if suitably chosen cathode layers may remain transparent up to 20 nm. Preferred thicknesses will depend upon the identity of the cathode material itself. For example, a light transmissivity of 30% or above can be attained by forming a Mg—Al alloy in a thickness of 14 nm. Examples of suitable transparent cathode materials are well known to those skilled in the art and are disclosed in, for example, U.S. Pat. Nos. 5,703,436 and 5,707,745.

The material used for forming the well-defining layer may be deposited on the substrate by any suitable technique known to those skilled in the art, e.g. spin coating. The thickness of the well-defining layer is such that it is sufficient to define the boundaries of the wells into which the solutions of the electroluminescent material are deposited by means of an ink jet printing process but not so high that there is significant danger of the thin cathode material breaking between the top of the layer of metal on the top surface of the well-defining layer and the electroluminescent layer. Thus, typically the well-defining layer is from 1.5-5 times the thickness of the electroluminescent layer, preferably from 1.5-4 times the thickness of the electroluminescent layer, and most preferably from 2-3 times the thickness of the electroluminescent layer. Where the well-defining layer is a photoresist layer, it may be formed from any photoresist material, examples of which include photosensitive polyimides and the like (see, for example, EP-A-0880303). Preferably, the photoresist used is a positive photoresist.

The organic electroluminescent layer can comprise one or more organic light emitting materials. Where there is more than one organic light emitting material, these can be disposed as separate, discrete layers or as mixtures of said materials in a single layer. Any organic light emitting materials can be used for the electroluminescent layer. Suitable examples include: conjugated polymers including poly(arylene vinylenes) such as poly-phenylene-vinylene (PPV) and derivatives thereof (see, for example, WO-A-90/13148); polyfluorene derivatives (see, for example, A. W. Grice, D. D. C. Bradley, M. T. Bernius, M. Inbasekaran, W. W. Wu, and E. P. Woo, Appl. Phys. Lett. 1998, 73, 629, WO-A-00/55927 and Bernius et al., Adv. Materials, 2000, 12, No. 23, 1737), particularly 2,7-linked 9,9 dialkyl polyfluorenes or 2,7-linked 9,9 diaryl polyfluorenes; polyspirofluorenes, particularly 2,7-linked poly-9,9-spirofluorene; polynaphthylene derivatives, polyindenofluorene derivatives, particularly 2,7-linked polyindenofluorenes; and polyphenanthrenyl derivatives; the contents of which references are incorporated herein by reference thereto.

Electroluminescent material is deposited by inkjet printing into the wells defined by the well-defining layer and the patterned metal layer. The inkjet composition used to deposit electroluminescent material comprises at least one solvent, at least one electroluminescent material and optional additives (e.g. additives for modifying viscosity, boiling point, etc. of the composition). Suitable electroluminescent compositions for inkjet printing will be apparent to the skilled person as disclosed in, for example, EP 0880303 and WO 01/16251. Suitable solvents include, for example, alkyl or alkoxy substituted benzenes, in particular polyalkylbenzenes wherein two or more alkyl substituents may be linked to form a ring.

The thickness of the electroluminescent layer or layers is not critical. The precise thickness of the layer or layers will vary depending upon factors such as the identity of the material or materials of the electroluminescent layer or layers and the identity of the other components of the device. However, typically the thickness of the electroluminescent layer (or combined thickness if there is more than one layer) is from 1 to 250 nm, preferably from 50 to 120 nm.

The substrate on which the organic electroluminescent device of the present invention can be formed is any which is typically used in such devices, examples of which include glass, quartz, crystalline substrates of Si, GaAs, ZnSe, ZnS, GaP and InP and transparent plastic. Of these, glass substrates are particularly preferred.

The hole injecting electrode can be formed from any material typically used for this purpose in electroluminescent devices. Examples of suitable materials include tin-doped indium oxide (ITO), zinc-doped indium oxide (IZO), indium oxide, tin oxide and zinc oxide, of which ITO is particularly preferred. The thickness of the hole injecting electrode will vary depending upon the identity of the hole injecting material and of the other components of the electroluminescent device. Typically, the electrode has a thickness of from 50 to 500 nm, particularly from 50 to 300 nm.

In a preferred embodiment, the walls of the well-defining layer have a positive profile such that the angle between the perpendicular to the substrate and said walls is greater than 0°. This helps to ensure continuity (i.e. no breakage of the cathode layer over both the electroluminescent layer and the layer of metal formed on the top surface of the well-defining photoresist layer).

In a further preferred embodiment, there is an offset between the perimeter of the well-defining layer and the perimeter of the layer of metal formed on the top surface of the well-defining photoresist layer. This construction is desirable where the properties of the well-defining layer such as its contact angle with the inkjet printed electroluminescent composition, hydrophilicity, etc. have been selected so to optimise filling of the well with electroluminescent material.

OLEDs are prone to degradation in the presence of moisture and oxygen and it is therefore desirable to provide a transparent encapsulant over the transparent cathode to provide a barrier against ingress of moisture and oxygen. Suitable transparent encapsulants include a layer of glass glued onto the substrate or a barrier stack comprising alternating layers of plastic and ceramic materials that combine to form a tortuous path for moisture or oxygen ingress.

In a further embodiment of the present invention, there is provided a method for the manufacture of a top-emitting display apparatus having a plurality of pixels, said method comprising the steps of:

(a) depositing an anode on a substrate;

(b) depositing a patternable insulating layer, the thickness of said patternable insulating layer being insufficient for it to serve as a spacer for an evaporation mask, on the anode layer deposited in step (a);

(c) depositing a layer of metal on the top surface of the patternable insulating layer formed in step (b);

(d) patterning the layer of metal deposited in step (c) and the patternable insulating layer to form a well-defining layer having the desired pattern of wells formed from the patternable insulating layer, and a patterned metal layer on the top surface of the well-defining layer;

(e) depositing by means of an ink-jet method an organic electroluminescent layer on the anode layer in each of the wells formed in step (d) to form said plurality of pixels; and

(e) depositing a transparent cathode layer both on the electroluminescent layer and the layer of metal on the top surface of the well-defining photoresist layer.

The material used to form the patternable insulating layer may be a photoresist that is treated using a suitable photomask in order to form the well-defining layer. Alternatively, the well-defining layer may be an etchable material, in particular an etchable polyimide, that may be patterned to form the well-defining layer by a wet etch or a dry etch process.

Preferably the anode may be deposited by means of sputtering. The well-defining layer, which is usually a positive photoresist, is deposited by spin coating of the photoresist material. The metal layer is then formed by thermal evaporation of the metal on the photoresist layer. In a preferred embodiment of the invention, patterning is achieved by first depositing a positive photoreist material on the metal layer (usually by means of spin coating), patterning the second photoresist layer thus formed by exposing it to UV light through a mask and rinsing, treating areas of the metal layer exposed by the mask thus formed by the patterned second photoresist layer with acid or alkali to etch the exposed areas and then treating the resulting device to UV light to expose the remainder of the patterned second photoresist layer and that part of the well-defining first photoresist layer that is not protected by the remaining part of the metal layer so as to form the well-defining resist layer.

A solution of electroluminescent material is deposited in each well of the device thus formed by an ink-jet device to form the pixels of the device. A thin transparent cathode layer is deposited on the electroluminescent layer and the layer of metal on the top surface of the well-defining photoresist layer is deposited by a suitable means such as thermal evaporation or electron beam evaporation.

The present invention may be further understood by consideration of the following non-limitative example, with reference to the following figures in which:

FIG. 1 shows a bottom-emitting organic light emitting device according to the prior art;

FIG. 1b shows a top-emitting organic light emitting device according to the prior art;

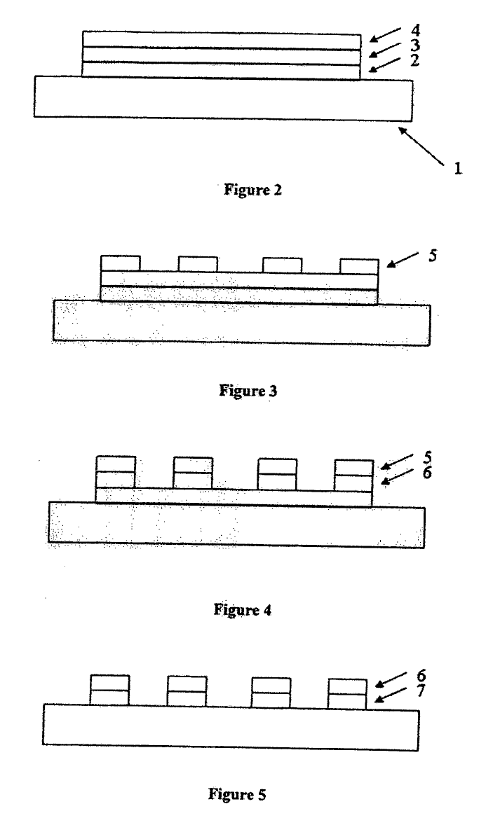

FIG. 2 shows the first step of the construction of a top-emitting organic light emitting device according to the present invention;

FIG. 3 shows the second step of the construction of a top-emitting organic light emitting device according to the present invention;

FIG. 4 shows the third step of the construction of a top-emitting organic light emitting device according to the present invention;

FIG. 5 shows the fourth step of the construction of a top-emitting organic light emitting device according to the present invention;

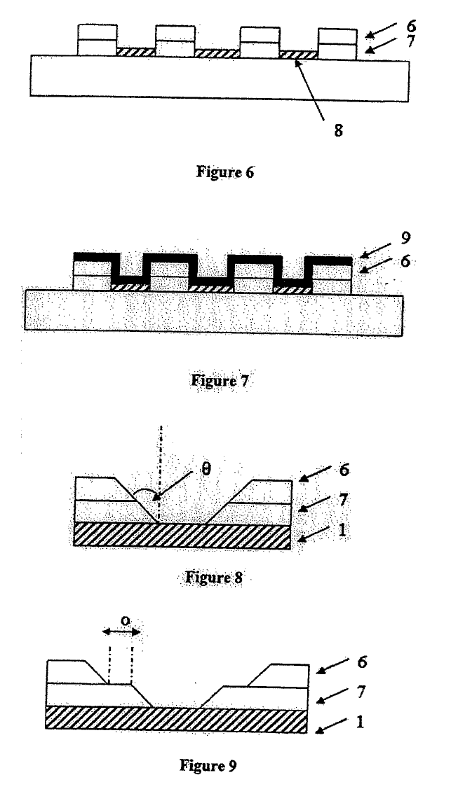

FIG. 6 shows the fifth step of the construction of a top-emitting organic light emitting device according to the present invention;

FIG. 7 shows the sixth step of the construction of a top-emitting organic light emitting device according to the present invention;

FIG. 8 shows a partial structure of an alternative top-emitting organic light emitting device according to the present invention; and

FIG. 9 shows a partial structure of another alternative top-emitting organic light emitting device according to the present invention

As shown in FIG. 2, onto a glass substrate 1 comprising active matrix circuitry and an anode is deposited a layer of positive photoresist by spin coating to form well-forming resist layer 2, a metal layer 3 formed by thermal evaporation of a conductive metal such as aluminium or chromium, and a layer of positive photoresist deposited by spin coating to form pattern-forming resist layer 4. As will be understood by the skilled person, the anodes are provided in a pattern corresponding to pixel areas of the end device, and drive circuitry is associated with each pixel.

FIG. 3 shows how the pattern-forming resist layer 4 produced above is then exposed to UV light through a mask and rinsed with a solvent to form patterned resist layer 5.

As illustrated in FIG. 4, metal layer 3 is treated with an acid or alkali to etch it and thus form a layer of patterned metal 6. Patterned resist layer 5 functions as a positive mask, resulting in metal layer 3 being etched in only those areas exposed by patterned resist layer 5 to produce patterned metal layer 6.

The device is then exposed to UV light, as shown in FIG. 5, thus exposing patterned resist layer 5 and well-forming resist layer 2 to UV light. Patterned metal layer 6 functions as a mask to protect underlying areas of well-forming resist from UV exposure. Thus, rinsing of the device results in patterned resist layer 5 being rinsed away completely and well-forming resist layer 2 being patterned so as to form well-defining resist layer 7.

Electroluminescent material 8 is now deposited by inkjet printing into the wells defined by well-defining resist layer 7 and patterned metal layer 6, as demonstrated in FIG. 6. The inkjet composition used to deposit electroluminescent material 8 comprises at least one solvent, at least one electroluminescent material and optional additives (e.g. additives for modifying viscosity, boiling point, etc. of the composition). Components of the electroluminescent compositions for inkjet printing will be apparent to the skilled person as disclosed in, for example, EP 0880303 and WO 01/16251.

Preferred components of the inkjet composition include the following:

electroluminescent material: conjugated polymers are preferred, including poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23)1737-1750 and references therein.

solvent: alkyl or alkoxy substituted benzenes, in particular polyalkylbenzenes wherein two or more alkyl substituents may be linked to form a ring

After formation of the pixels by ink-jet deposition of the electroluminescent material, a transparent cathode 9 is deposited over the substrate. The transparent cathode may comprise a single layer of conductive metal or a plurality of layers. Particularly preferred transparent cathode arrangements are:

a low workfunction metal sufficiently thin to be transparent in contact with the electroluminescent layer. Preferred low workfunction materials have a workfunction of no more than 3.5 eV, preferably no more than 3.2 eV, most preferably no more than 3.0 eV. Alkaline earth metals having these workfunctions in this range, in particular barium or calcium, are particularly preferred. Thin low workfunction materials may be deposited by relatively low energy processes such as thermal or electron beam evaporation that do not cause any damage to electroluminescent layer 8.

a thin layer of dielectric material capped with a thin metal layer. Preferred dielectric materials are metal oxides or fluorides, preferably fluorides. Preferred metal cations are alkaline or alkaline earth metals. Particularly preferred are fluorides of lithium, sodium, calcium and barium. Any thin metal layer may serve to cap the dielectric layer provided it retains its transparency, for example aluminium.

The transparent cathode 9 is typically capped with a further layer. This is because OLEDs are prone to degradation in the presence of moisture and oxygen and it is therefore desirable to provide a transparent encapsulant over the transparent cathode to provide a barrier against ingress of moisture and oxygen. Suitable transparent encapsulants include a layer of glass glued onto substrate 1 or a barrier stack comprising alternating layers of plastic and ceramic materials that combine form a tortuous path for moisture or oxygen ingress.

As will be appreciated by the skilled person, well-forming layer 2 must be a positive photoresist in order for exposed areas to be patternable following exposure to UV light. Pattern-forming layer 4, on the other hand, may be formed from a positive or negative photoresist for use with a positive or negative photomask respectively for formation of patterned resist layer 5. However, it is preferred that layer 4 is formed of a positive photoresist in order that removal of patterned resist layer 5 and patterning of layer 2 can occur in a single exposure and rinse step.

For simplicity of illustration, wells depicted in FIGS. 2-7 have perpendicular walls. However, it is preferred that the walls of the wells defining an individual pixel area have a positive profile as illustrated in FIG. 8, i.e. angle □ is greater than 0. This helps to ensure continuity (i.e. no breakage) of the cathode layer 9 over both the electroluminescent material 8 and the patterned metal layer 6.

In another preferred embodiment, however, the walls of the wells defining an individual pixel area have a negative profile, i.e. angle □ is less than 0. In this embodiment, a thick cathode layer 9 should be deposited that does not break at the edge of the well. One class of materials that retains transparency at such thicknesses are transparent conducting oxides (TCOs), in particular indium tin oxide and indium zinc oxide. The cathode layer 9 may consist of a TCO alone, however TCOs have relatively high workfunctions and so it is preferred that the cathode layer 9 further comprises a thin layer of low workfunction metal deposited over the electroluminescent layer 8 before deposition of the TCO. This thin metal layer may break at the well edge, resulting in no physical contact between the thin metal layer overlying electroluminescent material 8 and the patterned metal layer 6. However, an electrical connection between these may be formed via the TCO layer.

The structure shown in FIG. 8 results from described above wherein patterned metal layer 6 defines the pattern for well-defining layer 7, resulting in a patterned metal layer and well-defining layer that are self-aligned. In this instance, the surface properties of the metal layer 6 may be selected by appropriate surface treatment to form a high energy surface for inkjetted droplets, thus maximising the quantity of inaccurately deposited inkjet droplets flowing into the well (as opposed to remaining on the surface of metal layer 6).

However, FIG. 9 illustrates an alternative construction wherein an offset o is provided between the perimeter of the well forming layer and the perimeter of patterned metal layer in the region of a pixel. As will be appreciated by the skilled person, offset o may be formed by use of a mask in addition to (or as an alternative to) the masking effect provided by patterned metal layer 6 such that the offset area of the well-forming layer 2 is not exposed to UV light as part of the process for patterning of layer 2. Alternatively, offset o may be formed by choice of the positive photoresist and solvent used to dissolve well-forming resist layer 2 such that only part of the exposed area of well-forming resist layer 2 is dissolved.

Again, this construction is desirable where the properties of the well-defining layer 7 such as its contact angle with the inkjet printed electroluminescent composition, hydrophilicity, etc. have been selected so to optimise filling of the well with electroluminescent material 8.

1. A top-emitting display apparatus having a plurality of pixels, said apparatus comprising:
an anode formed on a substrate;
a well-defining layer, the thickness of said well-defining layer being insufficient for it to serve as a spacer for an evaporation mask;
an organic electroluminescent layer formed on the anode in each well of the well-defining layer to form said plurality of pixels;
a layer of metal formed on the top surface of the well-defining layer; and
a transparent cathode layer deposited such that it is formed both on the electroluminescent layer and the layer of metal on the top surface of the well-defining layer;
wherein the layer of metal and the well-defining layer are self-aligned, said metal layer being patterned from (one of) the same mask(s) as that used to pattern the well-defining layer.

2. A top-emitting display apparatus according to claim 1, wherein the organic electroluminescent layer is a patterned layer deposited by inkjet printing.

3. A top-emitting display apparatus according to claim 1, wherein the metal on the top surface of the well-defining layer is selected from the group consisting of aluminum and chromium.

4. A top-emitting display apparatus according to claim 1, wherein the metal on the top surface of the well-defining layer is deposited by thermal evaporation.

5. A top-emitting display apparatus according to claim 1, wherein the thickness of the layer of metal on the top surface of the well-defining layer is 0.1 μm-1 μm.

6. A top-emitting display apparatus according to claim 1, wherein the well-defining layer is formed from a photoresist patterned using a suitable photomask or from an etchable material patterned to form the well-defining layer by a wet etch or a dry etch process.

7. A top-emitting display apparatus according to claim 6, wherein the well-defining layer is formed from a photoresist.

8. A top-emitting display apparatus according to claim 1, wherein the transparent cathode comprises a low work-function conductive material that will allow the passage of at least some light through it.

9. (canceled)

10. (canceled)

11. (canceled)

12. A top-emitting display apparatus according to claim 1, wherein the transparent cathode comprises a low work-function metal sufficiently thin to be transparent in contact with the electroluminescent layer.

13. A top-emitting display apparatus according to claim 12, wherein the low work-function metal has a work-function of no more than 3.5 eV.

14. A top-emitting display apparatus according to claim 12, wherein the low work-function metal is an alkaline earth metal.

15. A top-emitting display apparatus according to claim 1, wherein the transparent cathode comprises a thin layer of dielectric material selected for the group consisting of metal oxides and metal fluorides capped with a thin metal layer.

16. (canceled)

17. A top-emitting display apparatus according to claim 15, wherein the metal of the metal oxide or metal fluoride is an alkaline metal or an alkaline earth metal.

18. A top-emitting display apparatus according to claim 1, wherein the material used for forming the well-defining layer is deposited on the substrate by spin coating.

19. A top-emitting display apparatus according to claim 1, wherein the well-defining layer is from 1.5-5 times the thickness of the electroluminescent layer.

20. (canceled)

21. (canceled)

22. A top-emitting display apparatus according to claim 1, wherein the organic electroluminescent layer comprises one or more organic light emitting materials comprising a conjugated polymer selected from the group consisting of poly(arylene vinylene) derivatives, polyfluorene derivatives, polyspirofluorene derivatives, polynaphthylene derivatives, polyindenofluorene derivatives and polyphenanthrenyl derivatives.

23. (canceled)

24. (canceled)

25. A top-emitting display apparatus according to claim 1, wherein the electroluminescent material is deposited by inkjet printing into the wells defined by the well-defining layer and the patterned metal layer.

26. (canceled)

27. (canceled)

28. A top-emitting display apparatus according to claim 1, wherein the walls of the well-defining layer have a positive profile such that an angle between the perpendicular to the substrate and said walls is greater than 0°.

29. A top-emitting display apparatus according to claim 1, wherein there is an offset between the perimeter of the well-defining layer and the perimeter of the layer of metal formed on the top surface of the well-defining photoresist layer.

30. A top-emitting display apparatus according to claim 1, wherein a transparent encapsulant is provided over the transparent cathode to provide a barrier against ingress of moisture and oxygen.

31. A method for the manufacture of a top-emitting display apparatus having a plurality of pixels, said method comprising:
(a) depositing an anode on a substrate;
(b) depositing a patternable insulating layer, the thickness of said patternable insulating layer being insufficient for it to serve as a spacer for an evaporation mask, on the anode layer of (a);
(c) depositing a layer of metal on the top surface of the patternable insulating layer of (b);
(d) patterning the layer of metal of (c) and the patternable insulating layer to form a well-defining layer having the desired pattern of wells formed from the patternable insulating layer, and a patterned metal layer on the top surface of the well-defining layer;
(e) depositing an organic electroluminescent layer on the anode layer in each of the wells of (d) to form said plurality of pixels; and
(e) depositing a transparent cathode layer both on the electroluminescent layer and the layer of metal on the top surface of the well-defining photoresist layer.

32. A method according to claim 31, wherein the material used to form the patternable insulating layer is a photoresist that is treated using a suitable photomask in order to form the well-defining layer.

33. A method according to claim 31, wherein the material used to form the patternable insulating layer is an etchable material that is patterned to form the well-defining layer by a wet etch or a dry etch process.

34. A method according to claim 31, comprising forming the metal layer on the top surface of the patternable insulating layer by thermal evaporation or electron beam evaporation of the metal on said patternable insulating layer.

35. A method according to claim 31, comprising depositing the anode is by sputtering.

36. A method according to claim 31, comprising patterning is by first depositing a positive photoresist material on the metal layer, patterning the second photoresist layer thus formed by exposing it to UV light through a mask and rinsing, treating areas of the metal layer exposed by the mask thus formed by the patterned second photoresist layer with acid or alkali to etch the exposed areas and then treating the resulting device to UV light to expose the remainder of the patterned second photoresist layer and that part of the well-defining first photoresist layer that is not protected by the remaining part of the metal layer so as to form the well-defining resist layer.

37. A method according to claim 31, comprising depositing a solution of electroluminescent material in each well of the device thus formed by an ink-jet device to form the pixels of the device.
